(19) United States
(12) Patent Application Publication
(10) Pub. No.: US 2024/0191336 A1
(43) Pub. Date: Jun. 13, 2024

(54) METAL MASK STRUCTURE

(71) Applicant: Darwin Precisions Corporation, Hsinchu County (TW)

(72) Inventors: KUAN-CHIEH FANG, Hsinchu County (TW); CHING-FENG LI, Hsinchu County (TW)

(21) Appl. No.: 18/377,316

(22) Filed: Oct. 6, 2023

(30) Foreign Application Priority Data
Dec. 13, 2022 (TW) 111147794

(51) Int. Cl. C23C 14/04

(52) U.S. Cl. CPC C23C 14/042

(57) ABSTRACT

A metal mask structure includes a plate and slits formed thereon. Each slit extends along a first direction and includes a first opening and a second opening formed on front and back surfaces, respectively, and communicating with each other to penetrate through the plate. A first longitudinal length of the first opening is smaller than a second longitudinal length of the second opening. The first opening has opposite first and second ends; the second opening has corresponding third and fourth ends. A first distance between the first end and the third end projected on the front surface parallel to the first direction is less than or equal to 200 μm. In a direction perpendicular to the first direction, a maximum width of the second opening is an extended width, and a width of the third end is a second end width less than or equal to the extended width.

### CROSS-REFERENCE TO RELATED APPLICATION

This application claims the priority benefit of Taiwan application serial no. 111147794 filed on Dec. 13, 2022. The entirety of the above-mentioned patent applications is hereby incorporated by reference herein and made a part of this specification.

### TECHNICAL FIELD

The present invention relates to a metal mask structure. Specifically, the present invention relates to a metal mask structure including a slit with a first opening communicating with a second opening.

### BACKGROUND

In electronic industry processes, in order to precisely manufacture a device or an assembly with predetermined circuit layout or pixel layout, it is necessary to use a metal mask with a predetermined pattern. For example, since the cathode ray tube technique evolved to the liquid crystal display technique, and then evolved to the organic light emitting display (OLED) technique, the display device gradually becomes slim, and the resolution is improved simultaneously. Therefore, the high resolution display devices are gradually and widely used in the modern electronic industry. However, high precision metal mask with predetermined pattern is necessary for manufacturing such high resolution display devices, for example, during the manufacture of red, green, and blue primary color pixels by evaporation. Moreover, when a fine metal mask (FMM) with the predetermined pattern is manufactured by processes such as base material preparation, lamination, exposure, development, first etching, second etching, and film removal, defects caused by insufficient etching or over etching may be generated due to a poor structural design of the metal mask. In particular, size or shape deviation may occur at the edge, end, or corner of the opening of the predetermined pattern due to the isotropy of chemical etching or the arrangement of etching process environment. Thus, the designed (predetermined) pattern may not be precisely defined on the metal mask, and defects may occur on the resulted metal mask, which is not suitable for use in precisely manufacturing the expected device or assembly.

### SUMMARY

### Technical Means to Solve the Problem

In order to solve the problem described above, an object of the present embodiment is to provide a metal mask structure, comprising: a plate having a front surface and a back surface and a plurality of slits extending along a first direction and respectively including a first opening formed on the front surface and a second opening formed on the second surface. The first opening communicates with the second opening to penetrate through the plate. A first longitudinal length of the first opening on the front surface and parallel to the first direction is smaller than a second longitudinal length of the second opening on the back surface and parallel to the first direction. The first opening includes a first end and a second end opposite to each other on the first longitudinal length, and the second opening includes a third end and a fourth end on the second longitudinal length corresponding to the first end and the second end, respectively. A first distance between the first end and the third end projected on the front surface parallel to the first direction is less than or equal to 200 μm. A maximum width of the second opening on the back surface and perpendicular to the first direction is defined as an extended width, a width of the third end of the second opening on the back surface and perpendicular to the first direction is defined as a second end width, and the second end width is less than or equal to the extended width.

### Comparing the Effectiveness with Prior Art

The metal mask structures of the embodiments of the invention can promote the precision of the metal mask structure. In particular, the precision of the shape of the opening edges or ends of the predetermined pattern of the metal mask structure can be improved. Thus, the precision of the predetermined pattern to be formed can be ensured when utilizing the metal mask structure. According to the metal mask structures of the embodiments, the openings formed by two etching processes on opposite surfaces of the plate body of the metal mask structure can be communicated with each other as expected, and the defects generated by over etching or insufficient etching when performing the first and second etching processes can be reduced. For example, but not limited to, the deformation or abnormal size of the opening of the predetermined pattern caused by conventional designs after the process is completed can be reduced. In particular, at the ends or the edges the opening may have the defects of overly wide or incomplete penetration. Therefore, the integrity and communication of openings formed by the first etching process and the second etching process can be ensured as expected, so the desired circuit layout or pixel layout, etc. can be generated during manufacturing the device or assembly by using the metal mask structure of the invention.

### BRIEF DESCRIPTION OF THE DRAWINGS

FIG. 1 is a schematic top view of a metal mask structure having a pattern area including slits according to an embodiment of the invention.

FIG. 2 is a partially enlarged schematic diagram of an exemplary region of the pattern area of FIG. 1.

FIG. 3 is a schematic cross-sectional view of a slit of the region R along the line A-A′ of FIG. 2.

FIG. 4 is a schematic view showing the configuration and relative size of the first opening and the second opening according to an embodiment of the invention.

FIG. 5 to FIG. 8 are schematic views of the first opening and the second opening according to different embodiments of the invention.

FIG. 9 is a schematic view of an exemplary slit viewing from the back surface according to an embodiment of the invention.

FIG. 10 is a schematic view of an exemplary slit viewing from the back surface according to another embodiment of the invention.

FIG. 11 is a schematic view of the exemplary slit of FIG. 10 viewing from the front surface.

FIG. 12 is a schematic view of the exemplary slit of FIG. 10 viewing from the front surface to show the edge at the end of the first opening.

### DETAILED DESCRIPTION

The following will describe various embodiments, and people skilled in the art should easily understand the spirits and the principles of the invention referring to the description and the figures. However, in spite of the embodiments specifically described in the specification, these embodiments are only used for examples, which are not construed as limitation or exhaustive constructions. Therefore, with regard to the people skilled in the art, variation and modification to the invention is obvious and can be easily obtained which is not separated from the spirit and the scope of the invention.

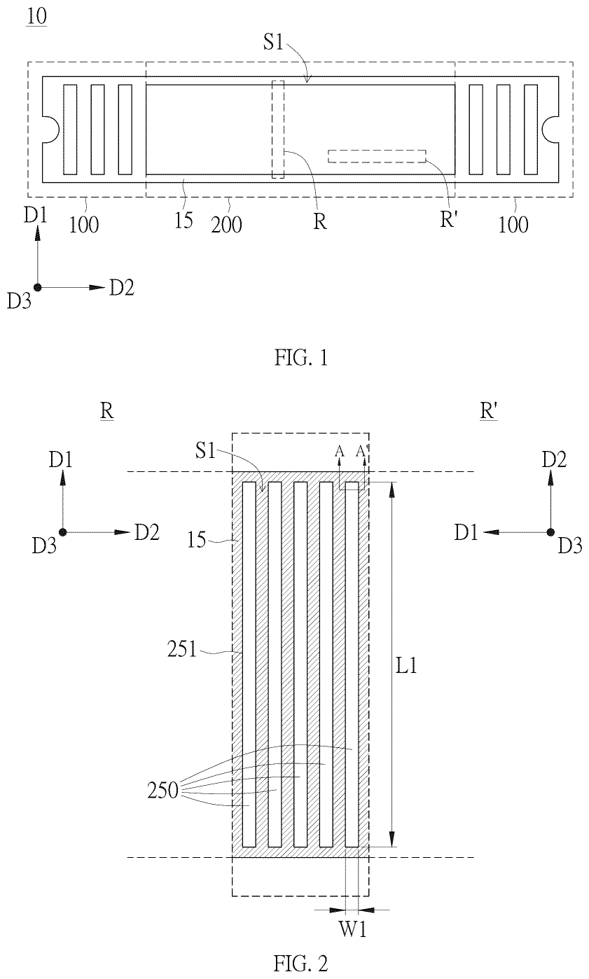

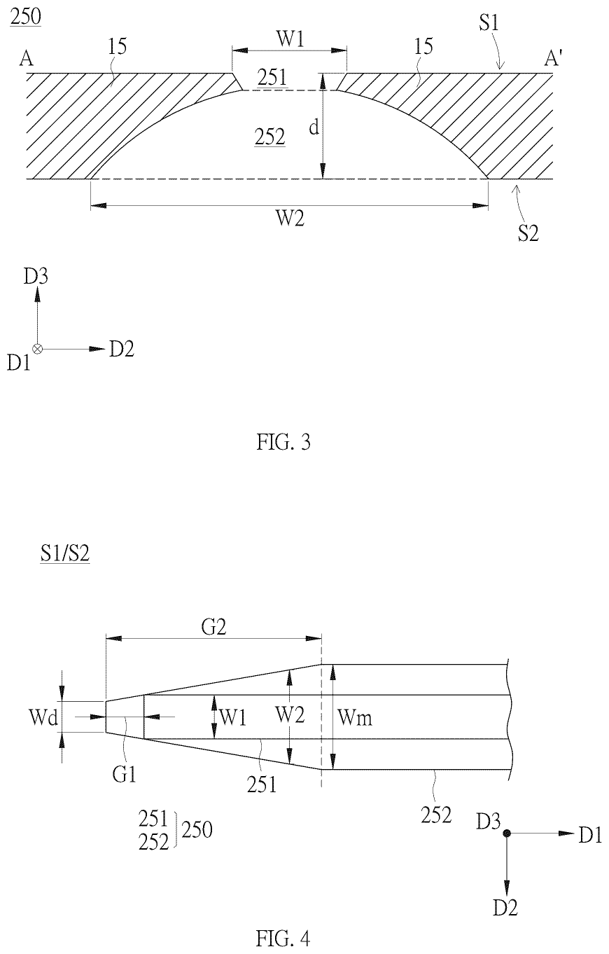

Referring to FIG. 1, the metal mask structure 10 of an embodiment of the present invention can include a net-opening area 100 and a pattern area 200. The net-opening area 100 is configured to be positioned and pulled, and the pattern area 200 is configured to form a predetermined pattern on a device or assembly to be processed. Specifically, patterns can be arranged in the pattern area 200 of FIG. 1. For example, referring to FIG. 2, which shows a partially enlarged schematic diagram of a region R or a region R′ of FIG. 1, the pattern area 200 can be arranged with strip-shaped slits 250 according to the predetermined pattern, and the major axis can be parallel to a first direction D1 (the region R) or a direction D2 (the region R′), but not limited thereto. As mentioned above, the pattern area 200 can be arranged with the strip-shaped slits 250 of the predetermined pattern along various directions, and the directions shown by the region R or the region R′ are only used for example, not limited thereto. The following content will mainly explain based on the region R as an example. Those skilled in the art should understand and presume arrangements along different directions, and the present invention will not elaborate these variations herein. As stated above, taking the region R as an example and referring to the cross-sectional view of the slits 250 of FIG. 3 as well as FIG. 2, the metal mask structure 10 includes a plate 15 with a front surface S1 and a back surface S2, and the plurality of slits 250 is formed on the plate 15. For example, the plate 15 can be a plate-shaped material made by Invar alloy, but not limited thereto. These slits 250 extend along the first direction D1, which is parallel to the first surface S1 and the back surface S2, and each slit 250 includes a first opening 250 formed on the front surface S1 and a second opening 252 formed on the back surface S2. For example, the first openings 251 can be formed by an (first) etching process during manufacturing the metal mask structure 10, and the second openings 252 can be formed by another (second) etching process during manufacturing the metal mask structure 10. However, the above-mentioned is only for example, and the first openings 251 and the second openings 252 can be manufactured by any suitable processes different from the first or second etching process. As described above, the first opening 251 communicates with the second opening 252 to penetrate the plate 15, so the slit 250 is formed penetrating through the plate 15 along a third direction D3, which is the thickness direction of the plate 15.

According to some embodiments, the depth “d” of the slit 250 in a direction perpendicular to the front surface S1 or the back surface S2 (i.e., the third direction D3) is defined as the slit depth “d”, and the slit depth “d” can be ranged between 15 μm and 100 μm, such as between 25 μm and 50 μm. That is to say, the plate 15 used for the main body of the metal mask structure 10 can have a thickness between 15 μm and 100 μm, such as between 25 μm and 50 μm, and the slit 250 can penetrate through the plate 15, so the first opening 251 communicates with the second opening 252.

Next, referring to FIG. 2 and FIG. 3, the first opening 251 of each of the slits 250 along the second direction D2 which is perpendicular to the first direction D1 has a width W1 on the front surface S1, and the second opening 252 of each of the slits 250 along the second direction D2 can have a width W2 on the back surface S2, wherein the width W2 is different from the width W1. In detail, although the first opening 251 communicates with the second opening 252, the first opening 251 and the second opening 252 exhibit different patterns or sizes on the front surface S1 and the back surface S2, respectively.

Further referring to FIG. 4 in conjunction with FIG. 2, FIG. 3, when the first opening 251 of the front surface S1 and the second opening 252 of the back surface S2 are placed on a same plane (for example, but not limited to both are projected on the front surface S1) and compared, a first longitudinal length of the first opening 251 on the front surface S1 and parallel to the first direction D1 is smaller than a second longitudinal length of the second opening 252 on the back surface S2 and parallel to the first direction D1. There is a first distance G1 between an end of the first opening 251 and an end of the corresponding second opening 252, and the first distance G1 is less than or equal to 200 μm. In addition, as shown in FIG. 4, the first opening 251 has a target width W1 of the pattern of the device or assembly to be formed. For example, according to some embodiments, a maximum width of the first opening 251 on the front surface S1 and perpendicular to the first direction D1 can be the target width W1, and the target width W1 can be less than or equal to 100 μm. In contrast, a maximum width of the second opening 252 on the back surface S2 and perpendicular to the first direction D1 can be an extended width Wm. The extended width Wm can be larger than the target width W1 and less than or equal to five times of the target width W1 (i.e., W1<Wm≤5*W1). Furthermore, a width W2 of the second opening 525 on the back surface S2 and perpendicular to the first direction D1 is a second end width Wd, and the second end width Wd can be less than or equal to the above extended width Wm.

Moreover, there is a second distance G2 between an end of the second opening 252 and a portion of the second opening 252 having the extended width Wm, and the second distance G2 is less than or equal to 1 mm.

Referring to FIG. 2 to FIG. 4, according to some embodiments, the slit 250 composed by the first opening 251 and the second opening 252 defined above is a strip-shaped slit, and the first longitudinal length L1 of the first opening 251 can be at least larger than or equal to three times of the target width W1 of the first opening 251.

As stated above, according to each embodiment of the present invention, based on the first opening 251 and the second opening 252 themselves and the relative sizes and the configurations thereof, the metal mask structure 10 can be manufactured with a desired range, and insufficient etching or over etching is not likely to occur. Therefore, the metal mask structure 10 can be used to more precisely form the predetermined pattern on the device or the assembly.

Hereinafter, referring to FIG. 5 to FIG. 8, different embodiments of the first opening 251 and the second opening 252 complying with the above size and configuration relationship will be illustratively explained. FIG. 5 to FIG. 8 all show that the first opening 251 on the front surface S1 and the second opening 252 on the back surface S2 are projected on the same plane, such as the front surface S1, and the following description will not elaborate again.

At first, referring to FIG. 5, in the slit pattern H1 of an embodiment, the first longitudinal length L1 of the first opening 251 on the front surface S1 and parallel to the first direction D1 can be less than the second longitudinal length L2 of the second opening 252 on the back surface and parallel to the first direction D1. In addition, the first opening 251 has a first end E1 and a second end E2 opposite to each other on the first longitudinal length L1, and the second opening 252 has a third end E3 and a fourth end E4 on the second longitudinal length L2. The third end E3 and the fourth end E4 correspond to the first end E1 and the second end E2, respectively. In detail, the first end E1 and the second end E2 are the farthest two ends of the first opening 251 apart along the first direction D1, and the third end E3 and the fourth end E4 are the farthest two ends of the second opening 252 apart along the first direction D1. Furthermore, the third end E3 is relatively near the first end E1 and away from the second end E2, so the third end E3 corresponds to the first end E1. On the other hand, the fourth end E4 is relatively near the second end E2 and away from the first end E1, so the fourth end E4 corresponds to the second end E2. The following will explain in detail as an illustrative example based on one end, people skilled in the art should be able to understand the situation of the opposite end, and will not elaborate again.

Referring to FIG. 5, the first distance G1 between the first end E1 and the third end E3 projected on the same plane (such as the front surface S1) and parallel to the first direction D1 is less than or equal to 200 μm. The maximum width W2 of the second opening 252 on the back surface S2 and perpendicular to the first direction D1 is the extended width Wm. The width W2 of the third end E3 of the second opening 252 on the back surface S2 and perpendicular to the first direction D1 is a second end width Wd, and the second end width Wd is less than the extended width Wm. In addition, the maximum width of the first opening 251 on the front surface S1 and perpendicular to the first direction D1 is the target width W1, and the target width W1 is less than or equal to 100 μm. As stated above, the extended width Wm can be larger than the target width W1 and less than or equal to five times of the target width W1.

Furthermore, according to the present embodiment, a portion of the second opening 252 having the extended width Wm is a section K, so the second distance G2 between the third end E3 and the nearest section K is less than or equal to 1 mm.

In this embodiment, the second distance G2 can be larger than the first distance G1.

As mentioned above, the first opening 251 and the second opening 252 can be formed in a predetermined configuration according to the slit pattern H1, so as to reduce defects generated by over etching or insufficient etching. Especially, the first opening 251 with predetermined pattern can be formed. Thus, the evaporation source can be disposed at, but not limited to, the side of the second opening 252, and the first opening 251 is disposed in contact with the device or assembly to be processed. Evaporation process is performed through the communicated first opening 251 and second opening 252, so the predetermined pattern corresponding to the first opening 251 is formed on the device or assembly to be processed.

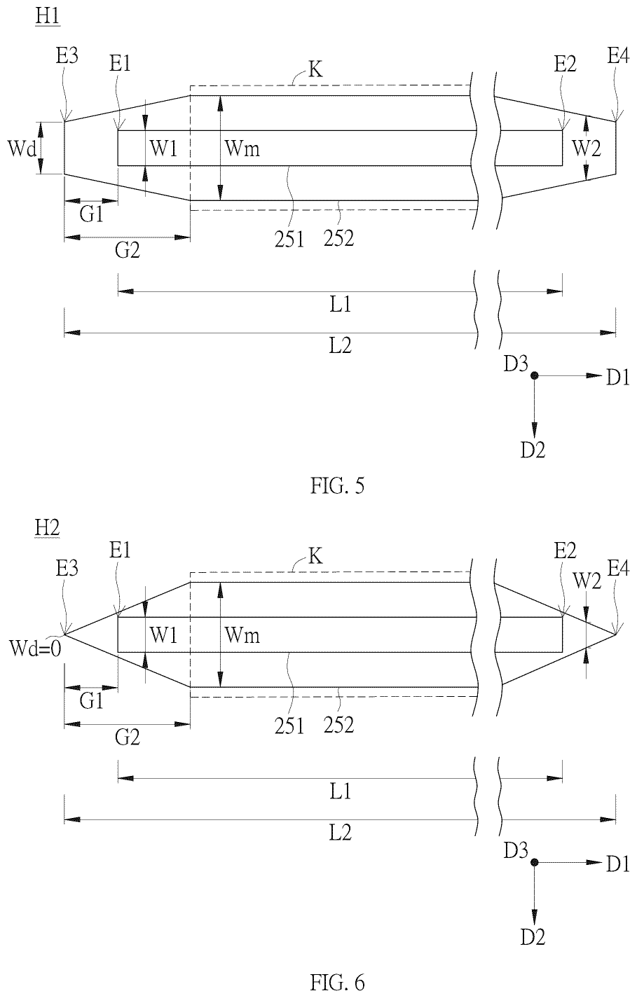

Next, please refer to FIG. 6. According to the slit pattern H2 of another embodiment of the present invention, the difference between the slit pattern H2 and the above slit pattern H1 is in that the second end width Wd can be zero. As described above, in the above embodiment, the opening width W2 of the second opening 252 along the entire length is always larger than the opening width W1 of the first opening 251; however, in the present embodiment, the opening width W2 of the second opening 252 may be less than the opening width W1 of the first opening 251 at a local region. For example, since a portion of the second opening 252 is gradually reduced from the section K of the extended width Wm to the third end E3, at which the second end width Wd is zero, the opening width W2 of the second opening 252 near the third end E3 can be smaller than the opening width W1 of the first opening 251. Therefore, in addition to reducing the defects generated by the over etching or insufficient etching, when the slit pattern H2 is used to manufacture the predetermined pattern of the device or assembly, the processing materials can be further centralized to enter the first opening 251 through the second opening 252, so as to enhance or improve utilization rate of the material.

Next, please refer to FIG. 7. According to the slit pattern H3 of yet another embodiment of the present invention, a difference between the slit pattern H3 and the above slit pattern H1 is in that the second end width Wd of the third end E3 of the second opening 252 is substantially equal to the extended width Wm. Thus, the second distance G2 between the third end E3 and the nearest section K having the extended width Wm is zero. Hence, the defects generated by the over etching or insufficient etching can be reduced. When the slit pattern H3 is used to manufacture the predetermined pattern of the device or assembly, a desired angle (such as the evaporation angle) passing through the second opening 252 into the first opening 251 can be achieved, and the effect of manufacturing the predetermined pattern (such as evaporation of a film) is improved.

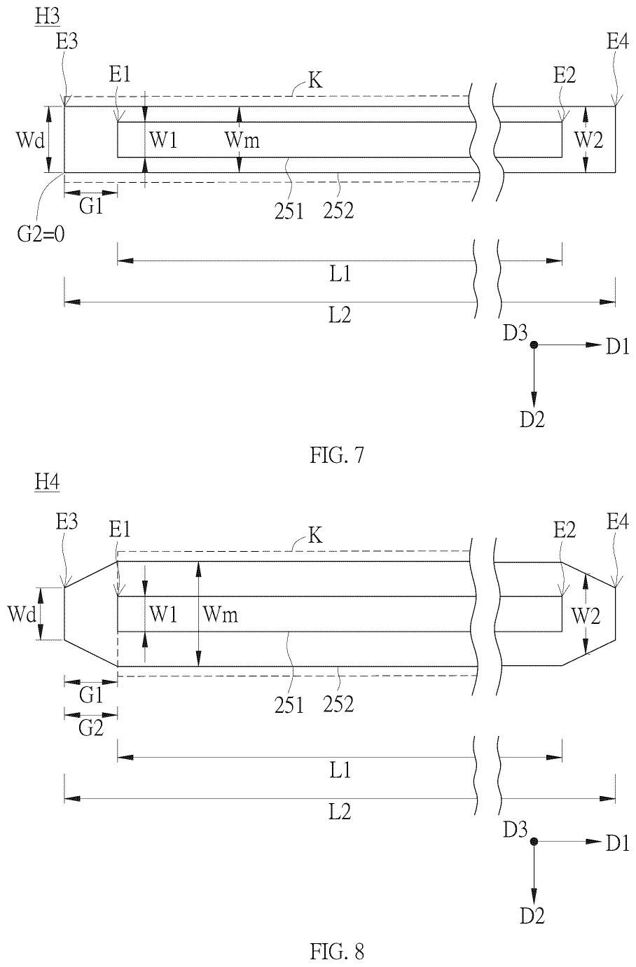

In addition, please refer to FIG. 8. According to the slit pattern H4 of further another embodiment, the difference between the slit pattern H4 and the slit pattern H1 is in that the second distance G2 between the third end E3 and the nearest section K having the extended width Wm is equal to the first distance G1 between the first end E1 and the third end E3 and parallel to the first direction D1. In other words, the section K having the extended width Wm is extended to be aligned with the first end E1 of the first opening 251. Hence, the defects generated by the over etching or insufficient etching can be reduced. When the slit pattern H4 is used to manufacture the predetermined pattern of the device or assembly, the uniformity of the angle and the distance passing through the second opening 252 into the first opening 251 can be kept, and the effect of manufacturing the predetermined pattern (such as evaporation of a film) is more uniform.

As described above, when the slit pattern in the embodiments of the invention falls within the predetermined design range, the first opening 251 and the second opening 252 themselves and the sizes and configurations thereof can have various patterns, so as to reduce or avoid the defects generated by the over etching or insufficient etching. Thus, the metal mask structure 10 can be used to precisely form the predetermined pattern on the device or assembly. In addition, according to different embodiments of the present invention, the first opening 251 can be formed in any closed geometric pattern, which has the first longitudinal length L1 in the major axis longer than the width W1 in the minor axis, and the second opening 252 can be formed in any closed geometric pattern, which has the second longitudinal length L2 in the major axis larger than the width W2 in the minor axis. For example, the closed geometric pattern can be a strip-shaped rectangle, hexagon, or oval. The geometric patterns of the first opening 251 and the second opening 252 disclosed herein are only examples, and the present invention is not limited thereto.

Next, please refer to FIG. 9, which shows a photo taken from the back surface S2, showing the first opening 251 and the second opening 252 of an actual product of the metal mask structure, which is designed according to the above design range in an embodiment of the present invention. In the present embodiment, the opening width W1 of the first opening 251 is set to 45 μm; the second end width Wd of the second opening 252 is set to 70 μm; the extended width Wm of the second opening 252 is set to 100 μm; the first distance G1 is set to 30 μm; the second distance G2 is set to 10 μm.

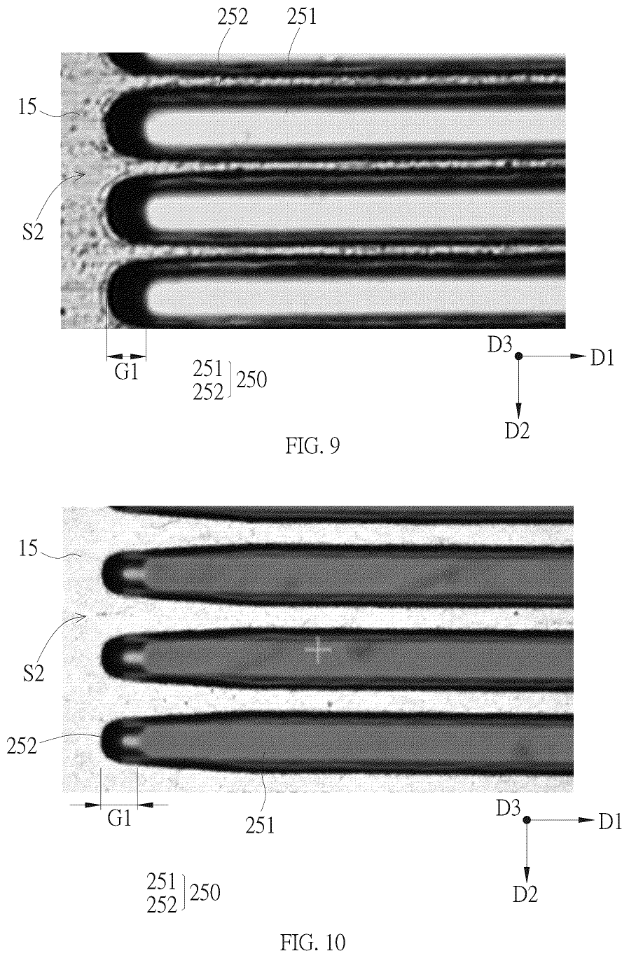

Further, please refer to FIG. 10, which shows a photo taken from the back surface S2, showing the first opening 251 and the second opening 252 of an actual product of the metal mask structure, which is designed according to the above design range in another embodiment of the present invention. In the present embodiment, the opening width W1 of the first opening 251 is set to 40 μm; the second end width Wd of the second opening 252 is set to 50 μm; the extended width Wm of the second opening 252 is set to 100 μm; the first distance G1 is set to 50 μm; the second distance G2 is set to 300 μm.

As mentioned above, according to the structural design of the first opening 251 and the second opening 252, the defects generated by over etching or insufficient etching of the entire slit (especially the first opening 251) can be reduced or avoided, so the precision of forming the predetermined pattern on the device or assembly by means of the first opening 251 can be enhanced.

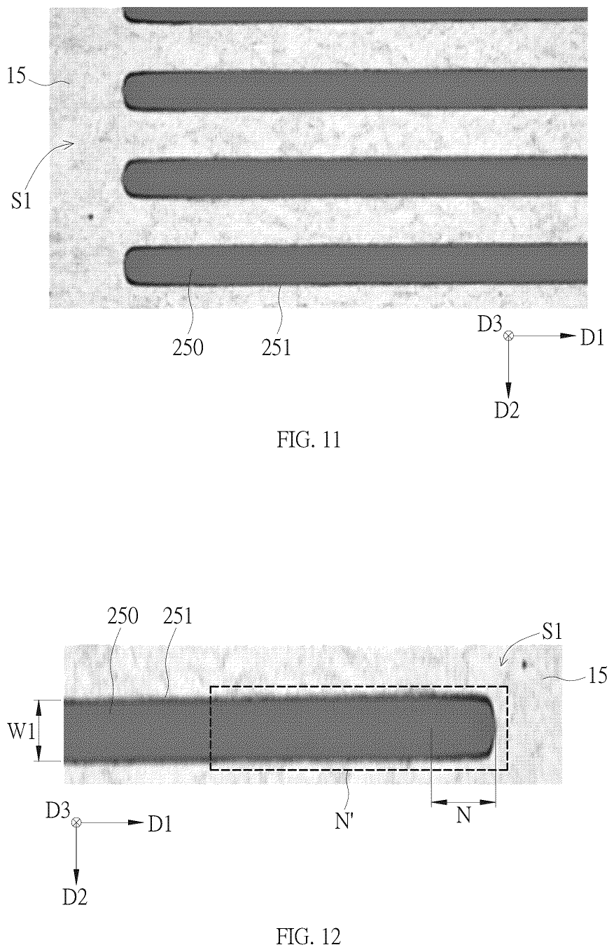

For example, take the embodiment of FIG. 10 as an example. Referring to FIG. 11, when observing the first opening 251 from the front surface S1, which is to be in contact with the device or assembly to be process, the first opening 251 has a relatively precise strip shape (such as a slit shape). Further referring to FIG. 12, FIG. 12 is an enlarged view of the end of the first opening 251 of FIG. 11. According to the present embodiment, it is assumed that the target opening width W1 of the expected first opening 251 (i.e., the width used to manufacture the predetermined pattern with high precision) is 40 μm. For the expected tolerance of 40±2 μm, the deviation section N whose width is beyond the range of 40±2 μm will be significantly reduced. For example, for the target opening width W1 being the same as 40 μm in conventional designs, the risk section N′ having a width over the range of 40±6 μm and extending along the first direction D1 by a range about 200 μm can be greatly reduced, so the influence range and deviation degree can be decreased. According to the present embodiment, the deviation section N whose width is over the range of 40±2 μm may extend about only 50 μm along the first direction D1, and the resulted actual deviation range is also small, such as 40±2 μm. As mentioned above, as shown in FIG. 11 and FIG. 12, the design of the present embodiment can significantly reduce or avoid the occurrence of non-uniform or imprecise defects, and the influence range and the deviation degree of the deviation section N can be significantly reduced.

As described above, the metal mask structure designed according to the present invention can reduce or avoid defects generated by over etching or insufficient etching of the communicated first opening and second opening. Therefore, the metal mask structure according to each embodiment of the present invention can be used to uniformly and precisely manufacture the predetermined pattern, so the precision of manufacturing the device and assembly can be improved.

The above is only some preferred embodiments of the present invention. It should be noted that the present invention can be varied and modified under the spirit and the scope of the present invention. People who skilled in the art should understand that the present invention is limited by the claims, and any possible varieties such as displacement, constitution, modification and transfer do not exceed the scope of the claims of the present invention.

What is claimed is:

1. A metal mask structure, comprising:
a plate having a front surface and a back surface; and
a plurality of slits extending along a first direction and respectively including a first opening formed on the front surface and a second opening formed on the second surface, wherein the first opening communicates with the second opening to penetrate through the plate,
wherein a first longitudinal length of the first opening on the front surface and parallel to the first direction is less than a second longitudinal length of the second opening on the back surface and parallel to the first direction, the first opening has a first end and a second end opposite to each other on the first longitudinal length, and the second opening has a third end and a fourth end on the second longitudinal length corresponding to the first end and the second end, respectively,
wherein a first distance between the first end and the third end projected on the front surface parallel to the first direction is less than or equal to 200 μm, and
wherein a maximum width of the second opening on the back surface and perpendicular to the first direction is defined as an extended width, a width of the third end of the second opening on the back surface and perpendicular to the first direction is a second end width, and the second end width is less than or equal to the extended width.

2. The metal mask structure according to claim 1, wherein a maximum width of the first opening in the front surface and perpendicular to the first direction is defined as a target width, and the target width is less than or equal to 100 μm.

3. The metal mask structure according to claim 2, wherein the extended width is larger than the target width and less than or equal to five times of the target width.

4. The metal mask structure according to claim 2, wherein the first longitudinal length of the first opening is larger than or equal to three times of the target width of the first opening.

5. The metal mask structure according to claim 1, wherein a depth of the slits perpendicular to the front surface or the back surface is defined as a slit depth, and the slit depth is ranged between 15 μm and 100 μm.

6. The metal mask structure according to claim 1, wherein a second distance between the third end and a nearest section of the second opening having the extended width is less than or equal to 1 mm.

7. The metal mask structure according to claim 6, wherein the second distance is equal to the first distance.

8. The metal mask structure according to claim 6, wherein the second distance is zero.

9. The metal mask structure according to claim 1, wherein the first opening is formed as a closed geometric pattern having the first longitudinal length in a major axis larger than a width in a minor axis, and the second opening is formed as a closed geometric pattern having the second longitudinal length in a major axis larger than a width in a minor axis.
